(19) United States
(12) Patent Application Publication
(10) Pub. No.: US 2013/0068288 A1
(43) Pub. Date: Mar. 21, 2013

(54) PHOTOVOLTAIC DEVICE WITH METAL-TO-GLASS MOISTURE BARRIER

(71) Applicants: Robert Stancel, Los Altos Hills, CA (US); Louis Basel, San Jose, CA (US)

(72) Inventors: Robert Stancel, Los Altos Hills, CA (US); Louis Basel, San Jose, CA (US)

(73) Assignee: Nanosolar, Inc., San Jose, CA (US)

(21) Appl. No.: 12/636,702

(22) Filed: Dec. 11, 2009

(51) Int. Cl. H01L 31/048; H01L 31/18

(52) U.S. Cl. 136/251; 438/64; 257/E31.117

(57) ABSTRACT

Methods and devices are provided for improved sensor systems. In one embodiment of the present invention, sensor system is provided that includes a sensor and sensor electronics integrated into the same ground plane.

### FIELD OF THE INVENTION

This invention relates generally to photovoltaic systems, and more specifically, to moisture resistant photovoltaic devices.

### BACKGROUND OF THE INVENTION

Traditional glass-glass photovoltaic modules use a moisture barrier tape around the perimeter of the module to keep moisture from damaging cells held therein. This moisture barrier tape provides a known moisture barrier capacity, but it does so at additional material cost and assembly time.

To alleviate this problem, some solar modules have transitioned to non glass-glass designs. Some embodiments may use a glass-foil or glass-flexible layer design. With this change in panel configuration, there may be a variety of changes that may be incorporated to improve panel manufacturability.

Although some moisture sealing techniques are known in the art, the potential for using other moisture techniques in new solar panel designs remains unexplored. Therefore, a need exists in the art for an improved, solar panel designs with improved moisture barrier configurations.

### SUMMARY OF THE INVENTION

Embodiments of the present invention address at least some of the drawbacks set forth above. Although not limited to the following, these improved embodiments are well suited for roll-to-roll, in-line processing equipment. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

A further understanding of the nature and advantages of the invention will become apparent by reference to the remaining portions of the specification and drawings.

### BRIEF DESCRIPTION OF THE DRAWINGS

FIG. 1 is a side view of a solar panel.

FIG. 2 shows a side cross-sectional view of a solar panel according to one embodiment of the present invention.

FIGS. 3 and 4 show side cross-sectional views of connection locations on a solar panel according to embodiments of the present invention.

FIGS. 5 and 6 show one technique for forming a metal-to-glass connection according to embodiments of the present invention.

FIGS. 7 through 11 show plan views of the underside of solar panels according to according to embodiments of the present invention.

FIGS. 12 and 13 show an electrical connector extending outward from the solar panel according to embodiments of the present invention.

FIGS. 14 and 15 show a solar panel with a connection seam located away from an edge line of the solar panel according to one embodiment of the present invention.

FIGS. 16 and 17 show solar panel(s) with diagonal connection seam according to one embodiment of the present invention.

FIGS. 18 and 19 show a solar panel having an electrical connection formed directly through a back side foil of one embodiment of the present invention.

FIG. 20 shows an ultrasonically welded connection according to one embodiment of the present invention.

FIGS. 21 through 27 patterns created in material by ultrasonic welding according to embodiments of the present invention.

FIGS. 28 through 29 show perspective views of portions of beams with opening configured to receive one or more tensioning members according to embodiments of the present invention.

FIG. 30 through 32 show embodiments of attachment members for use on the underside or of the front side of solar panels according to embodiments of the present invention.

FIG. 33 shows a side view of a portion of solar module with attachment locations for material according to embodiments of the present invention.

FIGS. 34 through 37 show bottom up plan views of portions of solar panels arrays mounted on beams according to embodiments of the present invention.

FIG. 38 shows a side view according to one embodiment of the present invention.

FIG. 39 through 43 show embodiments of attachment members for use on the underside or of the front side of solar panels according to embodiments of the present invention.

FIGS. 44 and 45 show side cross-sectional views of modules according to embodiments of the present invention.

FIGS. 46 and 47 show bottom up plan views of modules according to embodiments of the present invention.

FIGS. 48 and 49 show side exiting view of electrical connection according embodiments of the present invention.

FIG. 50 shows a barrier material with shaped cross-section to improve barrier properties according embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a roller optionally contains a feature for a thermally conductive film, this means that the conductive film feature may or may not be present, and, thus, the description includes both structures wherein a roller possesses the conductive film feature and structures wherein the film feature is not present.

### Metal-to-Transparent Layer Moisture Barrier

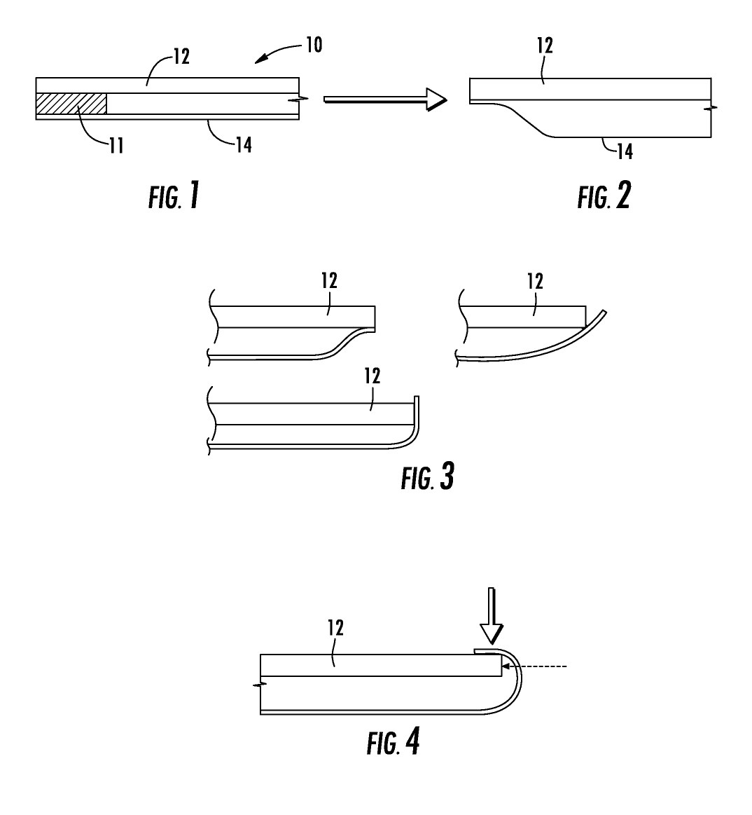

Referring now to FIG. 1, a cross-section of one type of glass-foil photovoltaic device 10 is shown. FIG. 1 shows that there is a moisture barrier material 11 between an upper transparent layer 12 and a back side layer 14. Thus, as seen in this figure, there is not a direct backside layer 14 attachment to the transparent layer 12 since the moisture barrier material 11 is therebetween. Some nonlimiting examples of moisture barrier material may include butyl rubber based material (with or without desiccant) or other moisture barrier edge seal materials.

Referring now to FIG. 2, one embodiment of the present invention will now be described. This embodiment shows that there is direct transparent layer 12 and a back side layer 14 contact at the perimeter 22 of the photovoltaic device. In this embodiment, there is no intermediate material between the transparent layer 12 and a back side layer 14. In one of several advantages, this removes the cost of having an intermediate material used for moisture barrier and adhesive properties. Removal of this material will reduced cost of to build the device. The removal of the moisture barrier material may also increase production throughput. Although the description herein may discuss direct metal-to-glass bonds, it should be understood that the embodiments of the present invention include the direct bonding of an easily weldable layer to a strong traditionally un-weldable layer. The easily weldable layer may be soft metal layer, metal-polymer layer, metal alloy layer, or combinations of the foregoing. The layer 14 comprises of a metal foil such as but not limited to stainless steel, titanium, aluminum, steel, iron, copper, molybdenum, a Mo coated stainless steel or aluminum foil, or alloys of the aforementioned. Optionally, the layer 14 may be but is not limited to zinc-aluminum alloy coated steel (such as Galvalume®), Corrtan® steel (a controlled corrosion steel with an adherent oxide), tin-coated steel, chromium coated steel, nickel-coated steel, stainless steel, galvanized steel, copper, conductive-paint coated metal foil such as weather resistant polymer containing carbon fiber, graphite, carbon black, nickel fiber, nickel particles, combinations thereof, or their alloys. In some embodiments, the layer 14 may be a plastic, a polymer or metallized polymer. Some embodiments may coat or otherwise form an electrically insulating material on at least one side of the layer 14. Some embodiments may have this electrically insulating layer on an outward facing surface, an inward facing surface, and/or both surfaces of layer 14.

Optionally, the layer 12 may be an encapsulation layer. By way of nonlimiting example, this encapsulation layer 12 may be a glass layer having a thickness of about 3.5 mm or less. Optionally, this layer 12 may be a thin glass layer having a thickness of about 3 mm or less. Optionally, this layer 12 may be a thin glass layer having a thickness of about 2 mm or less. By way of nonlimiting example, this thin-encapsulation layer 12 may be a thin glass layer having a thickness of about 1.5 mm or less. Optionally, this layer 12 may be a thin glass layer having a thickness of about 1 mm or less. Optionally, this layer 12 may be a thin glass layer having a thickness of about 0.5 mm or less. In one embodiment, glass of 1.0 mm or less may be used. In one embodiment, glass of 0.9 mm or less may be used. In one embodiment, glass of 0.8 mm or less may be used. In one embodiment, glass of 0.7 mm or less may be used. In one embodiment, glass of 0.6 mm or less may be used. In one embodiment, glass of 0.5 mm or less may be used. In one embodiment, glass of 0.4 mm or less may be used. In one embodiment, glass of 0.3 mm or less may be used. In one embodiment, glass of 0.2 mm or less may be used. In one embodiment, glass of 0.1 mm or less may be used. Optionally, it should be understood that the encapsulation layer 12 may be any of the protective layers disclosed in U.S. patent application Ser. No. 11/462,363 filed Aug. 3, 2006 and fully incorporated herein by reference for all purposes.

It should be understood that the layer 12 may be previously planar sheets that are shaped into a curled or curved configuration. Optionally, the layer 12 may be a tube for tubular shaped elongate solar cell. The ends of the tubular cells may have the direct metal to glass bonds to form the desired moisture seal. Optionally, some tubular cells may have bonds along lengthwise midline of the cell or a tubular housing structure. Optionally, some tubular cells may have bonds along lengthwise midline of the cell and/or only at the ends of the tube.

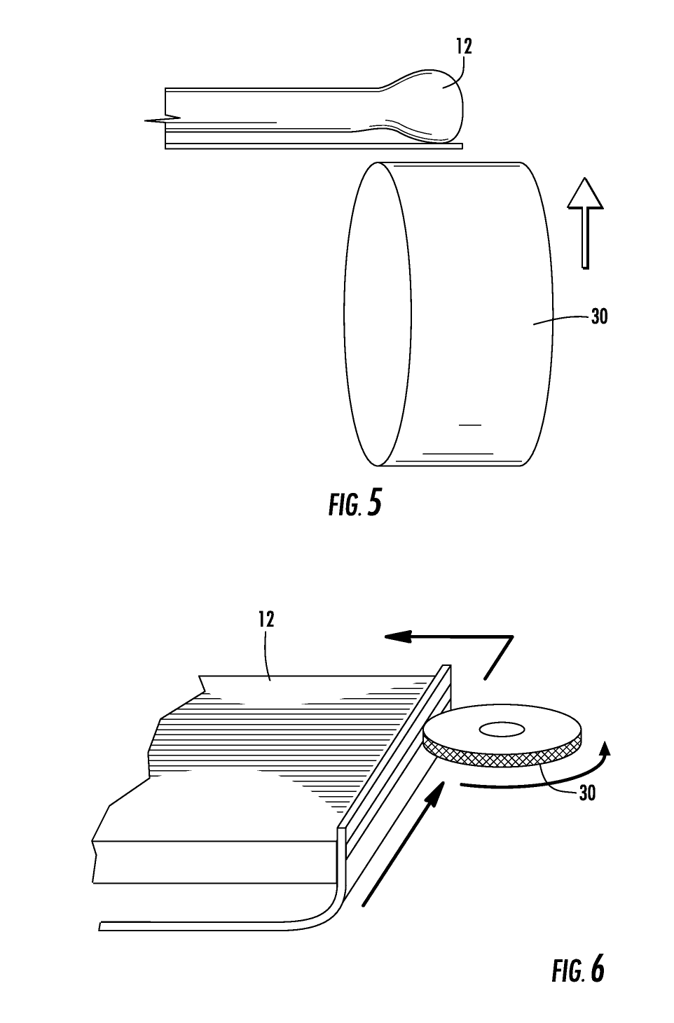

Referring now to FIG. 3, it should be understood that the location of the direct bond of the transparent layer 12 and a back side layer 14 can be selected as desired to maximize device performance. FIG. 3 shows that in some embodiments the bond is on the underside of transparent layer 12, on the side wall of transparent layer 12, and/or at an edge surface of the transparent layer 12. This would attach to back glass or for glass foil, it could be an edge seal, then ultrasonically weld something to the front side (not shading cells 15 mm as much as 18 as low as 5 mm). With glue, there is a greater glue width, but ultrasonic welding uses less area.

FIG. 4 shows that in some embodiments, the back side layer 14 is folded around the edge of the transparent layer 12 and contacts a front side of the layer 12. In this manner, a folded configuration is shown and the bond is positioned on the front side of the transparent layer 12. Optionally, there may also be a bond along the side and/or bottom surfaces of the transparent layer along with any topside ultrasonic welding. Some may use different bonding material techniques along each surface.

Referring now to FIG. 5, a still further embodiment is shown wherein the bonding apparatus 30 comprises of a rotational member that is ultrasonically driven to directly bond a metal layer to the upper layer 12. By way of nonlimiting example, one embodiment uses an ultrasonic welding wheel. Some embodiments may connect directly to the glass surface. Optionally, some may attach to a metal coated or sputtered surface on the glass using ultrasonic welding, soldering, or other attachment technique.

When bonding material through ultrasonic welding, the energy required comes in the form of mechanical vibrations. The welding tool (sonotrode) couples to the part to be welded and moves it in longitudinal direction. The part to be welded on remains static. Now the parts to be bonded are simultaneously pressed together. The simultaneous action of static and dynamic forces causes a fusion of the parts without having to use additional material.

Whereas in plastic welding, high-frequency vertical vibrations (20 to 70 kHz) are used to increase the temperature and plastify the material, the joining of metals is an entirely different process. Unlike in other processes, the parts to be welded are not heated to melting point, but are connected by applying pressure and high-frequency mechanical vibrations.

During ultrasonic metal welding, a complex process is triggered involving static forces, oscillating shearing forces and a moderate temperature increase in the welding area. The magnitude of these factors depends on the thickness of the workpieces, their surface structure, and their mechanical properties.

In one embodiment, the workpieces are placed between a fixed machine part, i.e. the anvil, and the sonotrode, which oscillates horizontally during the welding process at high frequency (usually 20 or 35 or 40 kHz).

Optionally, the most commonly used frequency of oscillation (working frequency) is 20 kHz. This frequency is above that audible to the human ear and also permits the best possible use of energy. For welding processes which require only a small amount of energy, a working frequency of 35 or 40 kHz may be used.

Ultrasonic welding has made possible the welding of various glasses, such as Borosilicate glass and Soda-lime glass, to aluminum sheet at the room temperature, both quickly and easily when compared to other welding methods. For example, the ultrasonic welding of A1050H and Borosilicate glass can be accomplished under the conditions of amplitude of ultrasonic horn top 20 μm, welding pressure 5 MPa, at a required duration of 0.4 s. When cleaned with forced ultrasonic vibration, the contact surfaces need no further surface treatment. Moreover, the material can be processed easily, the operation produces little heat, and there is virtually no resultant weakness of the product.

In contrast to plastics welding, the mechanical vibrations used during ultrasonic metal welding are introduced horizontally. Ultrasonic welding equipment is available from companies such as Sonobond Ultrasonics of West Chester, Pa.

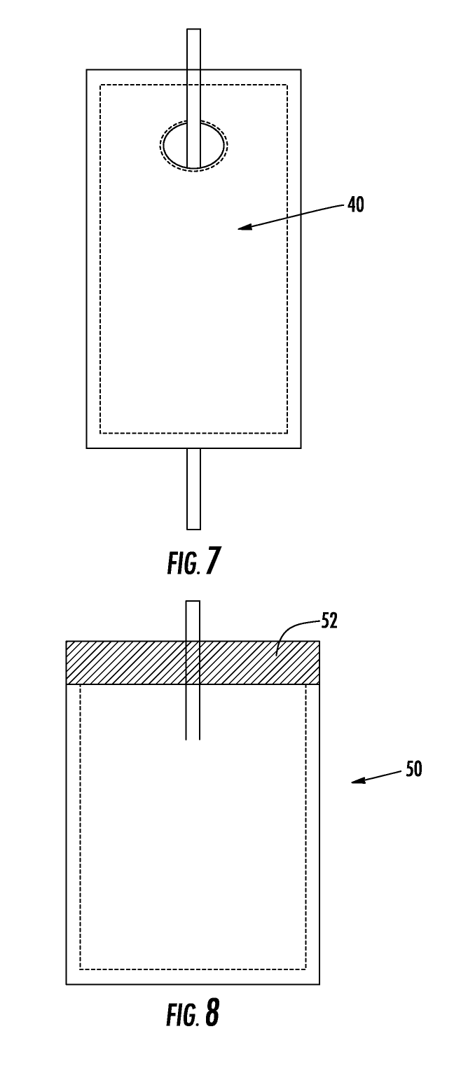

Referring now to FIG. 6, a still further embodiment is shown wherein the bonding apparatus 30 is oriented so that it translates along the perimeter of the photovoltaic device and bonds a side edge of the layer 12 to the backside layer 14.

Referring now to FIG. 7, one embodiment of the present invention comprises of a sealed photovoltaic device 40 wherein the entire rectangular perimeter of the device is sealed with direct glass-to-metal bonding. At least one electrical connection from the photovoltaic device 40 exits from an opening spaced apart from the outer perimeter. Optionally, even the perimeter around the opening for the electrical connector may be bonded.

Referring now to FIG. 8, a still further embodiment is shown wherein only three sides of the photovoltaic device 50 are direct glass-to-metal bonded. The fourth side has a moisture barrier material 52 between the front layer 12 and the backside layer 14. This may allow for exiting of the electrical lead between the moisture barrier materials 52 through the side or those portions of the side that is not direct metal-to-glass bonded.

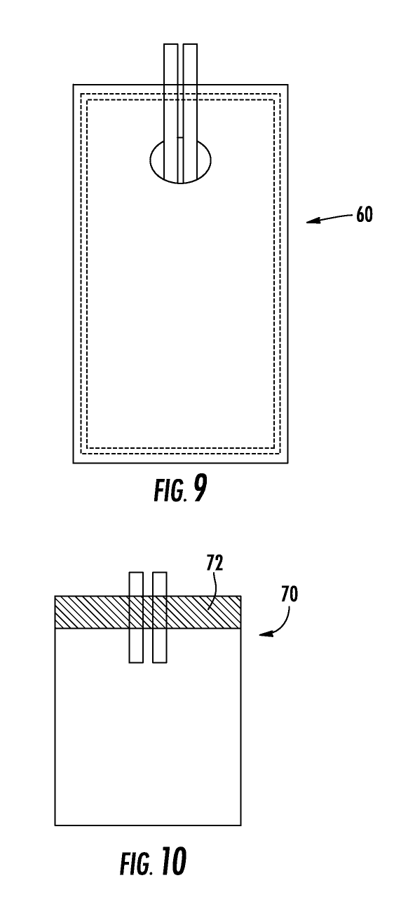

Referring now to FIG. 9, one embodiment of the present invention comprises of a sealed photovoltaic device 60 wherein the entire rectangular perimeter of the device is sealed with direct glass-to-metal bonding. At least two electrical connections from the photovoltaic device 60 exit from an opening spaced apart from the outer perimeter. Optionally, even the perimeter around the opening for the electrical connector may be bonded. Optionally, as seen in FIG. 9, more than one row of metal-to-glass bonding may be used. Some may use two or more rows or strips of metal-to-glass bonding to improve mechanical contact and to improve moisture barrier qualities. In one nonlimiting example, this may be achieved using dual head or multi-head ultrasonic welding heads to create direct metal-to-glass bonds. Some embodiment may use non-wheel based ultrasonic welding heads.

Referring now to FIG. 10, a still further embodiment is shown wherein only three sides of the photovoltaic device 70 are direct glass-to-metal bonded. The fourth side has a moisture barrier material 72 between the front layer 12 and the backside layer 14. This may allow for exiting of at least two electrical leads between the moisture barrier materials 72 through the side or select portions of the side that is not direct metal-to-glass bonded.

Referring now to FIG. 11, yet another embodiment is shown wherein only two sides of the photovoltaic device 80 are direct glass-to-metal bonded by bonds 82. The fourth side has a moisture barrier material 84 between the front layer 12 and the backside layer 14. This may allow for exiting of at least one electrical lead between the moisture barrier materials 84 through the side or select portions of the side that is not direct metal-to-glass bonded.

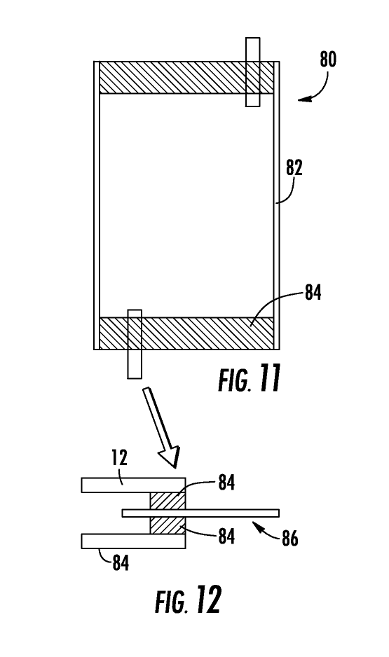

FIG. 12 shows a side view wherein the electrical lead 86 is shown exiting between layers of the moisture barrier material 82. It should be understood, of course, that some embodiments may have the electrical lead 86 pre-embedded into the moisture barrier. Optionally, some may have the electrical lead only on one side and use a housing+electrical resist layer to prevent contact between the electrical lead and the backside layer 14.

Referring now to FIG. 13, a still further embodiment is shown wherein an edge exiting electrical ribbon (insulated or non-insulated) exits from one edge of the sealed photovoltaic device. There is a select portion of moisture barrier material surrounding the exit location of the electrical ribbon. The other portions of this edge of the sealed photovoltaic device uses direct metal-to-glass bonding. This again may be a cost reducing feature as less material is used to seal around the exit location of the electrical ribbon.

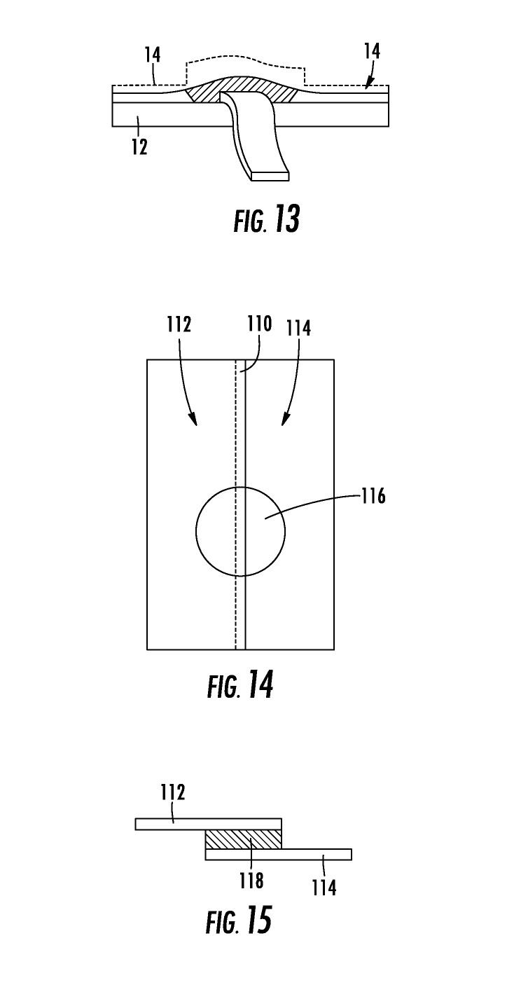

Referring now to FIG. 14, yet another embodiment of the present invention will now be described. FIG. 14 shows an embodiment wherein the seam 110 is along the midline with a first portion 112 and a second portion 114 of the backside layer on each side. An opening 116 may still be included to allow for exit locations for any electrical connectors for use with the photovoltaic device.

FIG. 15 provides a cross-sectional view of the area around seam 110. As seen in this figure, there is a pre-determined area of overlap. The bonding between the two layers may be by ultrasonic metal-to-glass bonding. Optionally, it may be by way of a moisture barrier material 118 positioned between the portions 112 and 114. The portions 112 and 114 may be wrapped around the photovoltaic device. Optionally, they may be ultrasonically bonded to the photovoltaic device.

FIG. 16 shows that the seam 120 is diagonally oriented and with bonds all around the perimeter. The diagonal seam 120 may be similar to that of FIG. 15, with or without a moisture barrier material 118 therebetween. As seen in FIG. 16, the back side layer may be welded, bonded, or otherwise attached all around the rectangular perimeter.

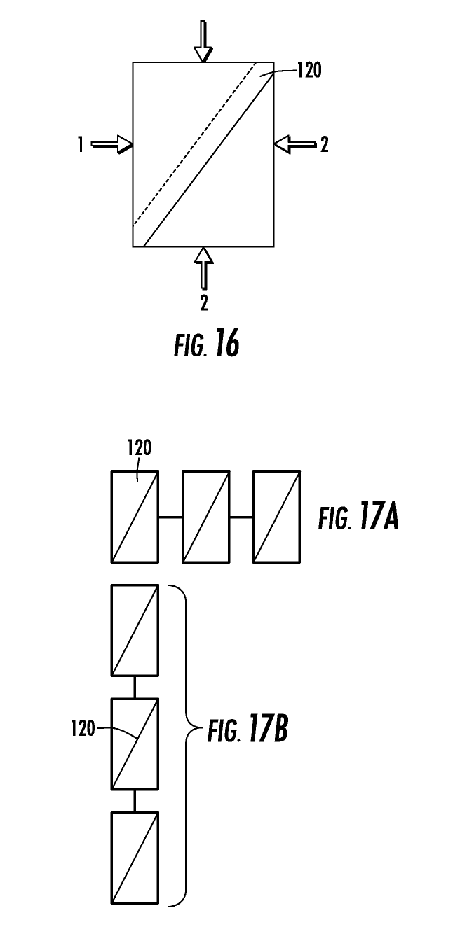

FIG. 17A shows that such photovoltaic devices or panels with the diagonal seam 120 may be oriented in a row such as that shown in this figure. Optionally, FIG. 17B shows that the photovoltaic devices or panels may be oriented to be a column.

Referring now to FIG. 18, a still further embodiment of the present invention will now be described. FIG. 18 shows an embodiment wherein there is a separate patch of material 132 used in addition to the back side layer 14. This allows for openings in the backside layer 14 to be sealed.

FIG. 19 shows a side view of the patch of material 132 used in addition to the back side layer 14. That patch of material 132 may be provided for contact purposes (electrical or mechanical). There may be moisture barrier material 134 between the patch of material 132 and the back side layer 14.

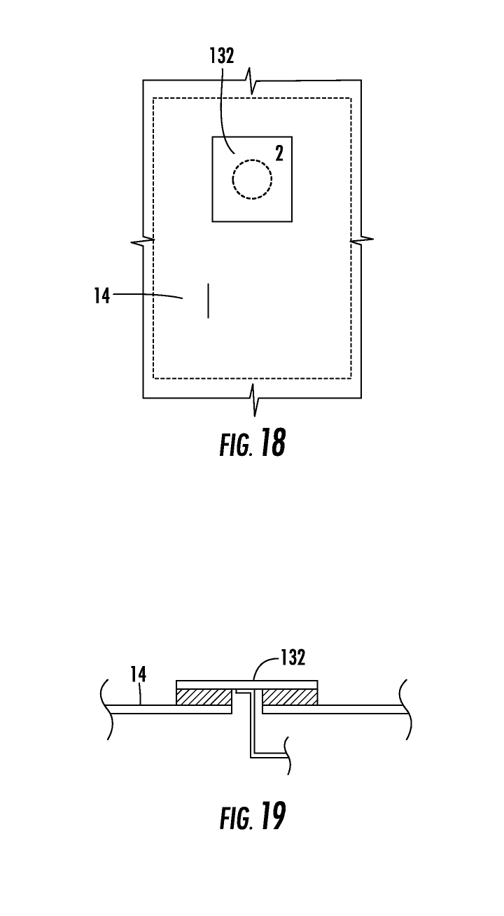

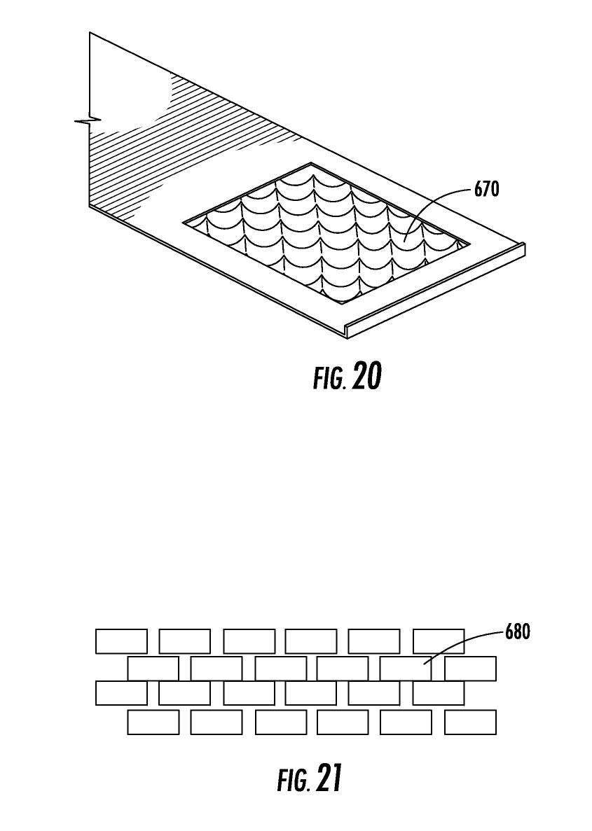

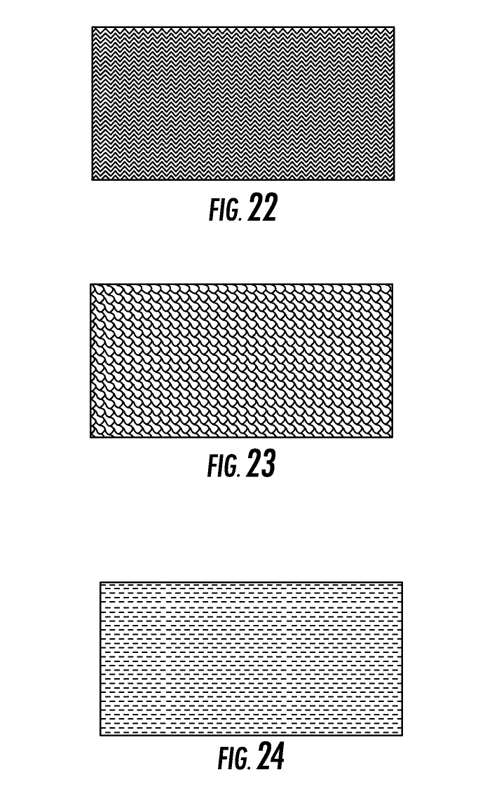

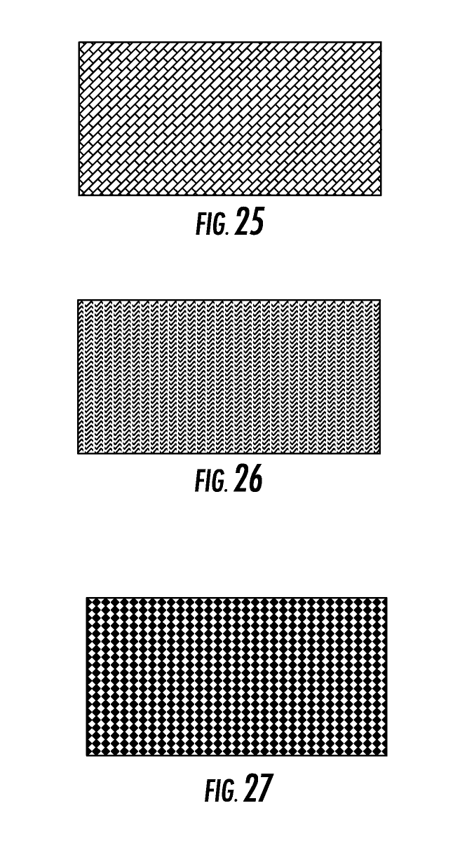

FIG. 20 shows one embodiment which leave a texture 670 as shown. Optionally, FIG. 21 shows another embodiment wherein a different pattern 680 of alternating blocks is used to minimize the presence of a moisture path through the bonded zones or to improve contact. FIGS. 22 through 29 show a variety of other possible patterns created in the material with ultrasonic welding heads. FIG. 22 shows a continuous wavey-line pattern. FIG. 23 shows a fish-scale pattern. FIG. 24 shows a plurality of discontinuous line pattern. FIG. 25 shows a diagonal block pattern. FIG. 26 shows a plurality of discontinuous wave patterns. FIG. 27 uses a regular diamond pattern. Some embodiments of the present invention may use both a direct metal-to-glass bond and a moisture barrier material. This may allow for a thinner strip of moisture barrier material to be used. The ultrasonically created weld may also withstand the pull tests as previously mentioned herein.

Optionally, the width of the metal-to-glass bond may be in the range of about 1 mm or less. Optionally, the width of the metal-to-glass bond may be in the range of about 2 mm or less. Optionally, the width of the metal-to-glass bond may be in the range of about 3 mm or less. Optionally, the width of the metal-to-glass bond may be in the range of about 4 mm or less. Optionally, the width of the metal-to-glass bond may be in the range of about 5 mm or less. Optionally, the width of the metal-to-glass bond may be in the range of about 6 mm or less. Optionally, the width of the metal-to-glass bond may be in the range of about 7 mm or less. Optionally, the width of the metal-to-glass bond may be in the range of about 8 mm or less. Optionally, the width of the metal-to-glass bond may be in the range of about 9 mm or less. Optionally, the width of the metal-to-glass bond may be in the range of about 10 mm or less. There may be one or more strips of metal-to-glass bond per side. There may be two or more strips of metal-to-glass bond per side. There may be three or more strips of metal-to-glass bond per side. The ultrasonically created weld may also withstand the pull tests as previously mentioned herein.

FIG. 28 shows a bottom up plan view of one embodiment of the present invention wherein a tensioning cable or elongate member 550 that provides support to the solar panel 552 in uplift and downward load is coupled to the module by connectors or brackets 554. A central beam 556 may support the solar panel 552. Bracket 554 may be fastened, glued, ultrasonically welded, or attached by other technique to the solar panel 552. The delayed fracture of glass under tension in cable 550 can allow for larger panels to be made that can still withstand 2400 pa load without failure. In one embodiment, the panel is mounted so that the cable 550 is in tension even when there is no load on the panel (other than the panel's own weight). In one embodiment, the amount of tension may be in the range of about 1000 lb to about 16000 lb. Optionally, the amount of tension may be in the range of about 500 lb to about 20000 lb. Optionally, the amount of tension may be in the range of about 100 lb to about 20000 lb. The ultrasonically created weld may also withstand the pull tests as previously mentioned herein.

FIG. 29 shows a variation wherein a single, 4 corner clip 560 is used to simultaneously couple four corners of the different adjacent modules with the same clip 560 or bracket. For ease of illustration, not all solar panels and not all brackets are shown. It should be understood that most embodiments of the bracket 560 would couple to four different solar panels.

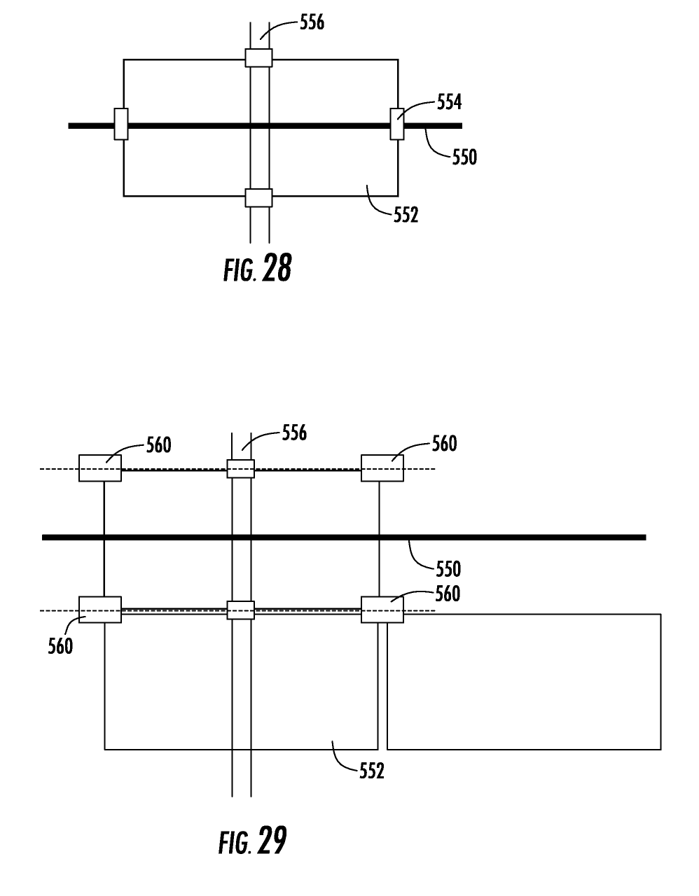

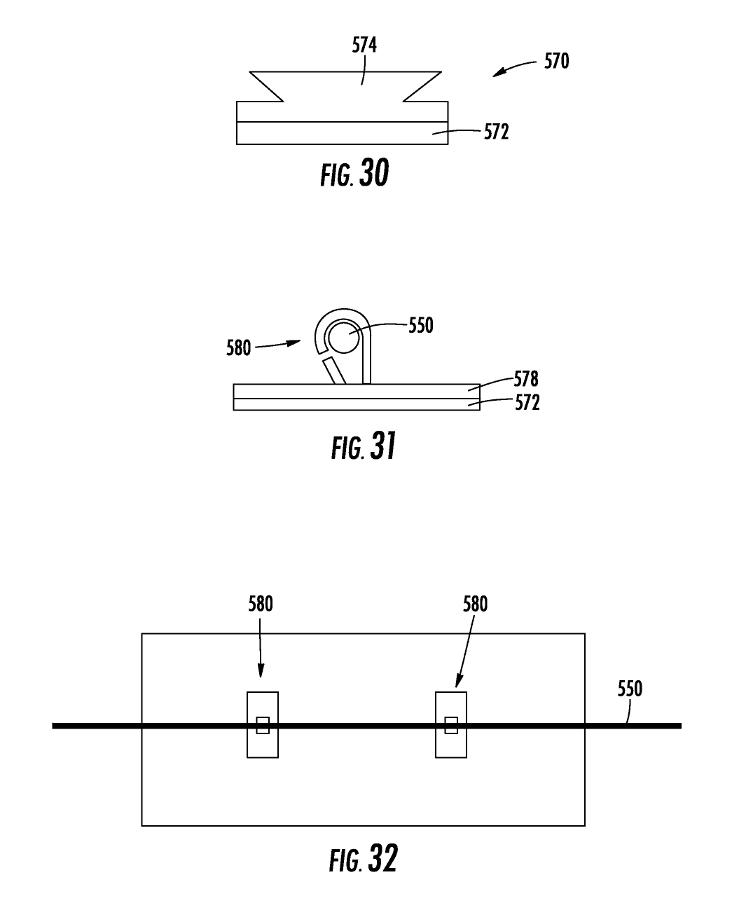

FIG. 30 through 31 show side view of brackets or shaped members that may be ultrasonically welded or attached by other metal-to-glass methods to the back layer of the solar panel. The ultrasonically created weld may also withstand the pull tests as previously mentioned herein. FIG. 30 shows that the member 570 may have a layer 572 to facilitate ultrasonic welding or attachment to the glass. In this embodiment, this may be aluminum or aluminum alloy that is able to bond to the glass. This layer 572 and any overlying layer of more rigid material (such as but not limited to stainless steel) may be simultaneously ultrasonically welded to the glass of the solar panel. The member 570 may include geometric features such as a dove tail 574 to allow attachment of other devices to the anchor points created through the ultrasonic welding. The ultrasonically created weld may also withstand the pull tests as previously mentioned herein.

Referring now to FIG. 31, yet another embodiment of the present invention is shown wherein a quick release clip or attachment 580 may be used to hook to cable 550. This may be coupled to a layer 572 with a stainless steel or other more rigid layer 578.

FIG. 32 shows that the members 570 or 580 may be coupled to the backside of the solar panel and allow for coupling of the solar panel at one or more locations so that uplift and downward forces are all minimized by the cable 550.

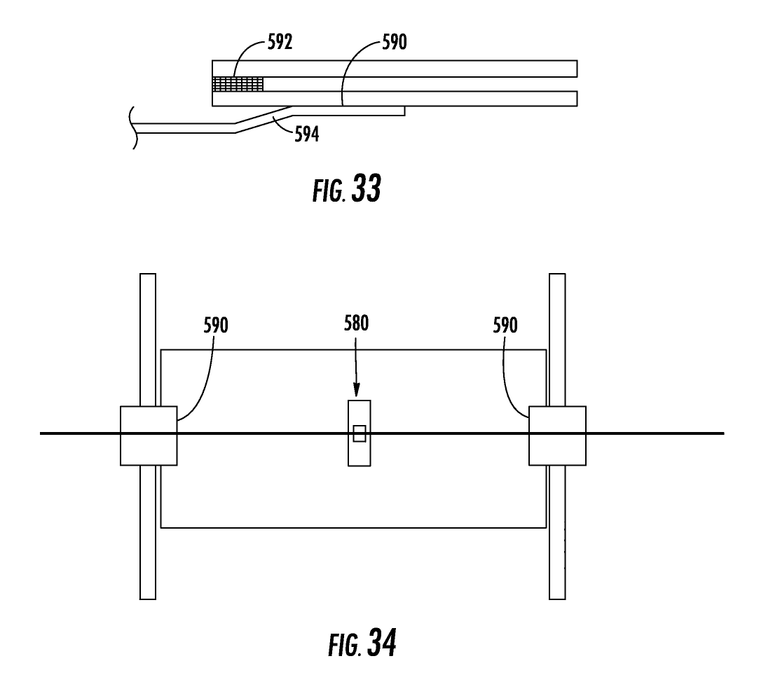

Referring now to FIG. 33, it should be understood that the location of where the connector or bracket is coupled to the frontside and/or the backside of the solar panel may have an impact on the reliability of any edge seal. The location 590 of the connection, in this embodiment, should at least be at a location within the perimeter of the barrier material 592. In this manner, the tension or other forces through the plane of the solar panel are not directly acting in the areas over or under the location of the barrier material 592. Optionally, some embodiments have at least a safety gap of at least 100% to 200% of the width of the barrier material 592 between the closest edge of the barrier material and the location 590. Optionally, other embodiments do not have the bend 594, and may be in contact with the module, but the attachment point is still located at a position spaced apart from the perimeter barrier material or any material that may be sensitive to stress from the tensioning.

FIG. 34 shows one embodiment wherein the embodiment has at least one member 580 on the backside of the solar panel and having the attachment points 590 within the perimeter of any barrier layer. Again, glue, metal-glass welding, ultrasonic welding, adhesive, screws, set screws, clamps, and/or fasteners may also be used to secure the member 580 or attachment points/locations 590 to the solar panel. Some embodiments use non-creeping attachment methods such as the ultrasonic welding of metal to glass.

Referring to FIG. 35, a still further embodiment is shown wherein attachment members 580 for the cable 550 is aligned along one edge of the solar panel that includes junction boxes or electrical connection boxes 600. In this manner, the packing density is not additionally impacted as the members 580 are along the same edge as the electrical connection boxes 600. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass.

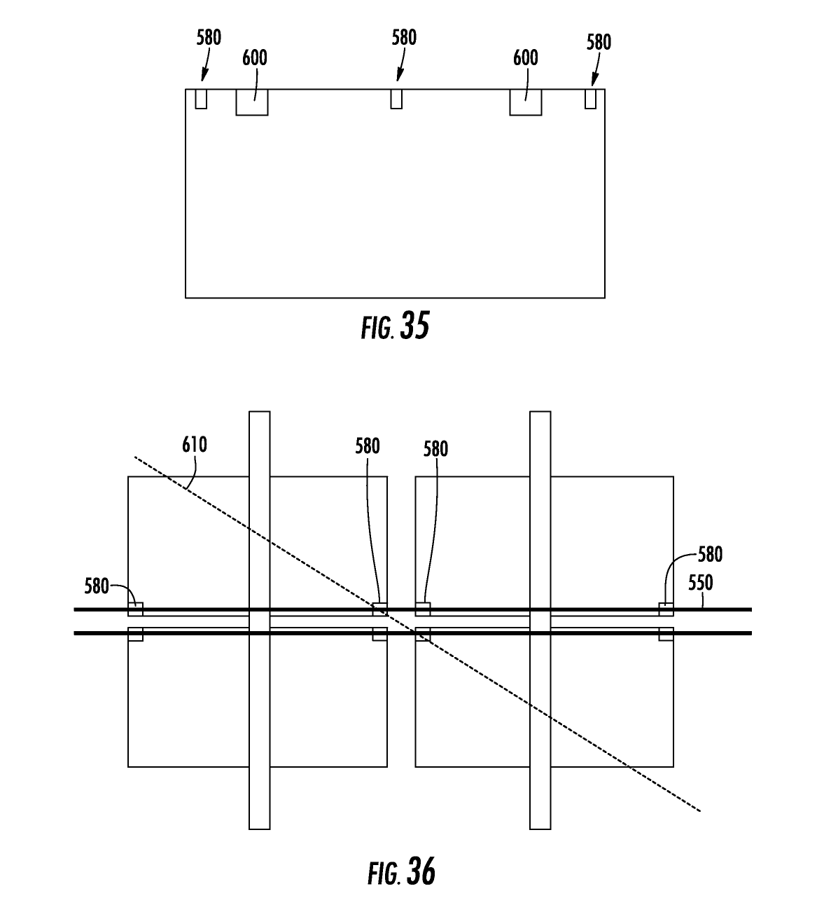

FIG. 36 shows that in one embodiment, the cable 550 may be aligned to be along one edge of the solar panel. FIG. 71 also shows that not every cable is in a longitudinal or a latitudinal orientation. There may also be angled cables 610 used with or in place of those longitudinal or latitudinal cables. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass.

FIG. 37 shows yet another embodiment wherein the solar panel is support between two beams 556 while using 550 may be aligned to be along one edge of the solar panel through the members 580. Of course, for all of the embodiments herein, additional solar panels used to complete the array such as shown in FIGS. 41-44 are not shown for ease of illustration. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass. The ultrasonically created weld may also withstand the pull tests as previously mentioned herein.

Optionally, the width of the metal-to-glass bond may be in the range of about 1 mm or less. Optionally, the width of the metal-to-glass bond may be in the range of about 2 mm or less. Optionally, the width of the metal-to-glass bond may be in the range of about 3 mm or less. Optionally, the width of the metal-to-glass bond may be in the range of about 4 mm or less. Optionally, the width of the metal-to-glass bond may be in the range of about 5 mm or less. Optionally, the width of the metal-to-glass bond may be in the range of about 6 mm or less. Optionally, the width of the metal-to-glass bond may be in the range of about 7 mm or less. Optionally, the width of the metal-to-glass bond may be in the range of about 8 mm or less. Optionally, the width of the metal-to-glass bond may be in the range of about 9 mm or less. Optionally, the width of the metal-to-glass bond may be in the range of about 10 mm or less. There may be one or more strips of metal-to-glass bond per side. There may be two or more strips of metal-to-glass bond per side. There may be three or more strips of metal-to-glass bond per side.

By suitable choice of the width of the bond, the number or strips of bond, and/or the bond pattern (if any), the oxygen permeability of the metal-glass barrier can be made less than about 1 cc/m²/day, 0.1 cc/m²/day, 0.01 cc/m²/day, 10⁻³ cc/m²/day, 10⁻⁴ cc/m²/day, 10⁻⁵ cc/m²/day, 10⁻⁶ cc/m²/day, or 10⁻⁷ cc/m²/day. Similarly, the water vapor permeability of the metal-glass barrier can be made less than about 1 g/m²/day, 0.1 g/m²/day, 0.01 g/m²/day, 10⁻³ g/m²/day, 10⁻⁴ g/m²/day, 10⁻⁵ g/m²/day, 10⁻⁶ g/m²/day, or 10⁻⁷ g/m²/day.

Referring now to FIG. 38, a side view is shown wherein there is an metal-to-glass edge seal 700 located along a perimeter of the solar panel. The interior 702 may be filled with pottant. This particular embodiment may include an opening 704 in the backsheet where electrical connections may exit the module. One advantage of ultrasonic welding to form the metal-to-glass barrier is that there is no cure time with ultrasonic welding.

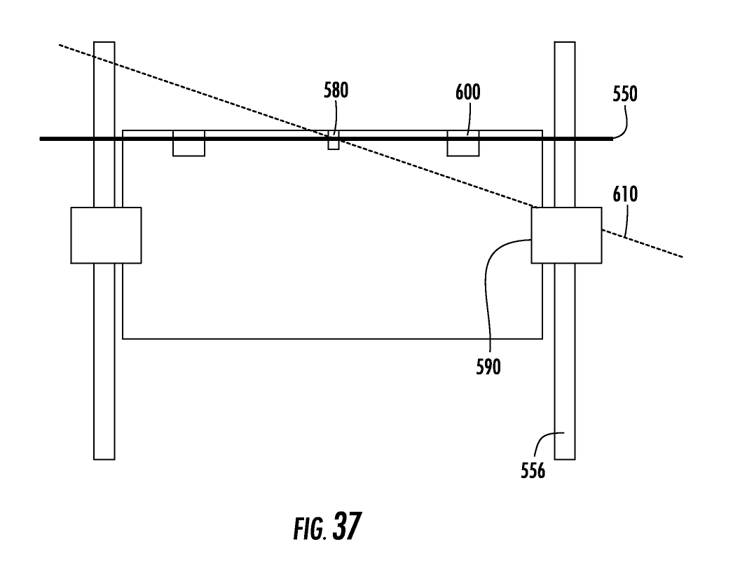

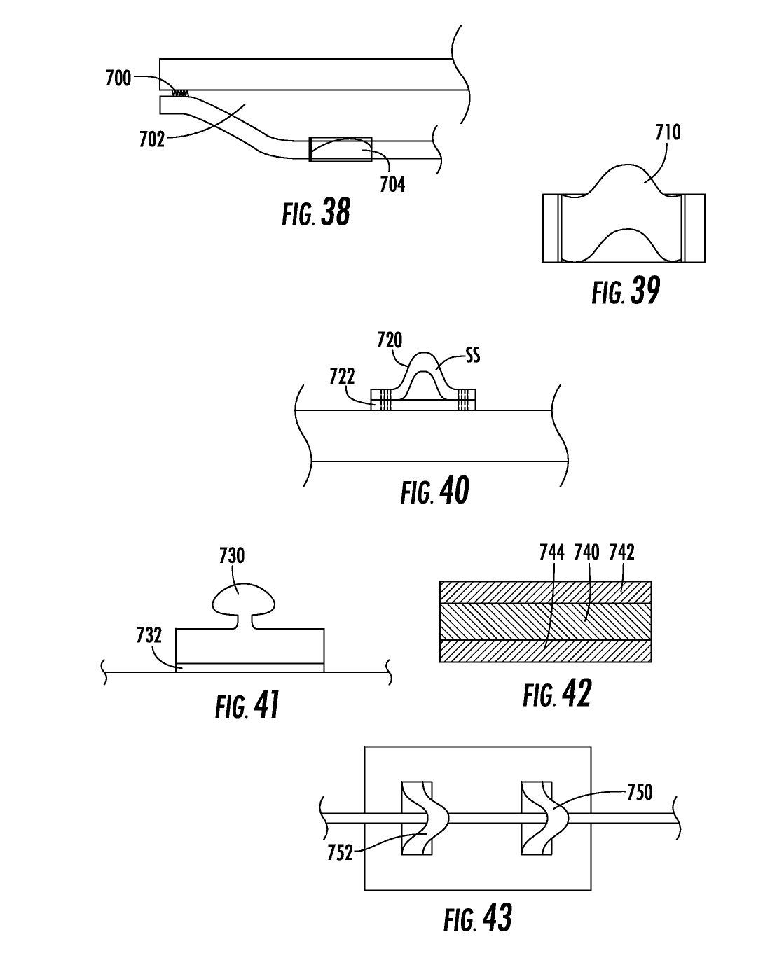

Referring to FIG. 39, this ultrasonic welding would allow some detail or structure 710 on the panel that is ultrasonically welded that interfaces with a detail on another panel. This embodiment may be a loop for securing rods, wires, tensioners, or beam to the module.

FIGS. 40 through 43 show additional views of structures that may be attached to the backside of the module to facilitate attachment of material to the module. FIG. 40 shows a hoop 720 with a stainless steel strength member with an aluminum layer 722 that is ultrasonically welded to the module.

FIG. 41 shows an embodiment wherein the attached structure has a clover profile retaining member 730. There may be an aluminum layer 732 that is ultrasonically welded to the module.

FIG. 42 shows that in some embodiments, the strengthening or stiffening layer 740 may be located inside two layers 742, 744 of other metals such as but not limited to aluminum with is more easily coupled by metal-to-glass connection than the stiffening layer.

FIG. 43 shows two hoop structures 750 and 752 coupled to the back side of a module for mounting purposes.

Referring now to FIG. 44, a side cross-sectional view where there is an electrical insulator layer 760 over the foil layer 762 that forms the barrier layer on the underside of the module. This figure also shows an opening 763 in those layers 760 and 762 that allows an electrical connector 764 to connect directly to the solar cell at location 765. A moisture barrier 766 is positioned around the entire opening to prevent exposure of any interior of the module except for the metal back side of the module. This embodiment uses an ultrasonic perimeter seal along the outer perimeter of the module. The idea is to have a cell in the packaging with a hole beneath the cell, with some insulator/spacer that prevents foil from touching, a doughnut of edge tape, so that one can solder or weld directly to back of cell with and edge both around. The other end is a welded tab, with an insulator, and the welded tab goes through two layers of material. Cut the layers until one reaches the back of the cell. The stack may comprise of aluminum, dielectric insulator, then cell.

Optionally, in some embodiment, the foil 762 may be electrically charge carrying and covered with insulation except at the location where it may be exposed to allow for electrical connection. Other possibility is that either one of the contacts does contact the vapor barrier aluminum foil, and then an insulator does not connect, but there is a tab weld back foil so that the entire back panel vapor barrier is a contact and the other is a the corner on the last cell in the string. Solderable, weldable, or connection technique may be used.

With foil, there could be a hole on the back side. For various glass foil embodiments, there could be an ultrasonically welded foil and then a rubber seal that covers all around the opening. More desirable to have outside insulated so there does not need to be grounding. Epdm, PET, etc . . .

As seen in FIG. 45, electric insulation or insulation can be on the inside of the foil 762, and then foil should be grounded.

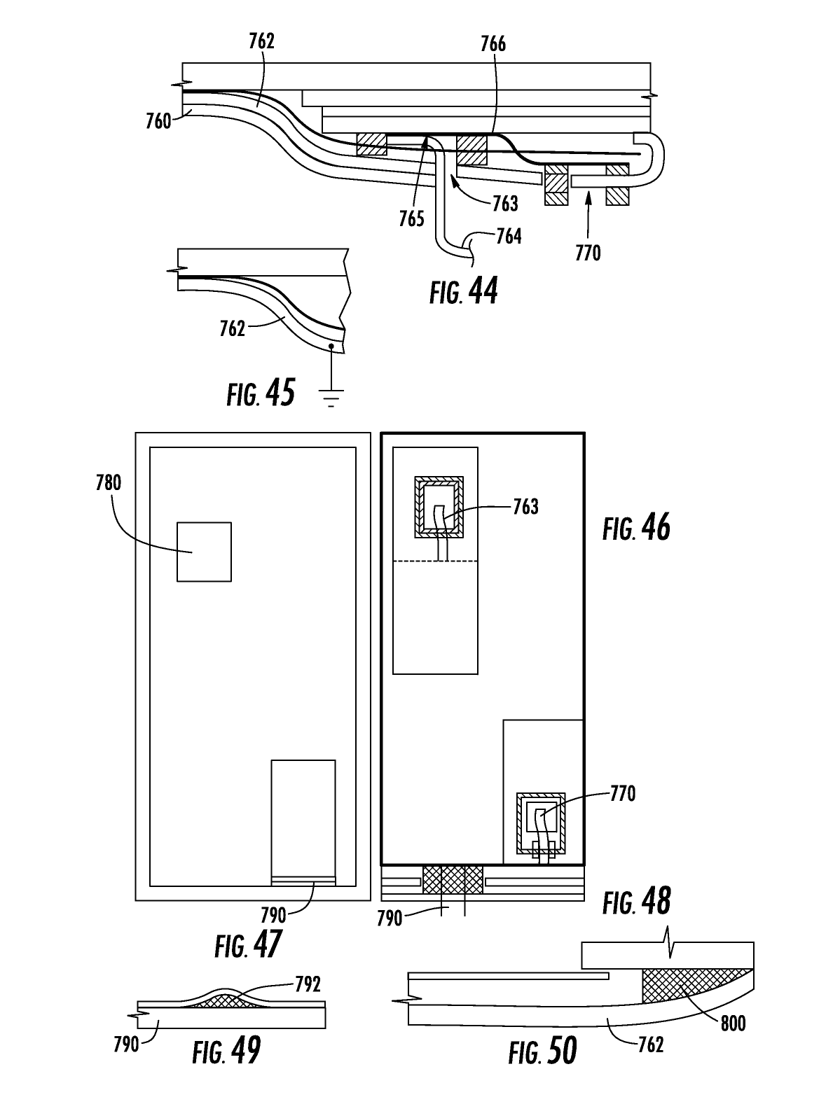

FIGS. 46 and 47 show backside plan views of modules with metal backside foi.s FIG. 46 show where there is a connection to a cell through opening 763 and at 770. These are at the beginning and end of the cell strings in the module.

FIG. 47 shows an embodiment where the foil 762 is charge carrying and a first electrical connection location 780 is used with an edge exiting electrical connector 790. An barrier material 792 such as those recited any where herein may also be used to seal the edge exit of the electrical connector 790. FIGS. 48 and 49 show additional views of the edge exit.

FIG. 50 shows a still further embodiment wherein the edge moisture barrier 800 (used with or without ultrasonic barrier) is tapered or wedge shaped so that a small aperture area is exposed to any moisture entering and that the amount of barrier with or without desiccant increases as the wedge gets thicker to increase absorption should any moisture attempt to enter.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it is possible to do the assembly of the module layers in vacuum, subatmospheric, and/or an inert gas environment. Some embodiments may use no encapsulant material between the photovoltaic cells inside the panel and the layer 12 and/or layer 14. The photovoltaic panel is a fully sealed device and one or more of these layers may be removed. Optionally, some embodiments may use thinner layer of encapsulant or may have reduced panel lamination time since the system is already pre-sealed. By way of nonlimiting example, the thickness of encapsulant between layer 12 and the cell may be 0.5 mm or less. Optionally, the thickness of encapsulant between layer 12 and the cell may be 0.4 mm or less. Optionally, the thickness of encapsulant between layer 12 and the cell may be 0.3 mm or less. Optionally, the thickness of encapsulant between layer 12 and the cell may be 0.2 mm or less. Optionally, the thickness of encapsulant between layer 12 and the cell may be 0.1 mm or less. Optionally, the thickness of encapsulant between layer 12 and the cell may be 0.05 mm or less.

Furthermore, those of skill in the art will recognize that any of the embodiments of the present invention can be applied to almost any type of solar cell material and/or architecture. For example, the absorber layer in the solar cell may be an absorber layer comprised of silicon, amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, Cu—In, In—Ga, Cu—Ga, Cu—In—Ga, Cu—In—Ga—S, Cu—In—Ga—Se, II-VI materials, IB-VI materials, CuZnTe, CuTe, ZnTe, other absorber materials, IB-IIB-IVA-VIA absorbers, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a thickness range of about 1 nm to about 200 nm should be interpreted to include not only the explicitly recited limits of about 1 nm and about 200 nm, but also to include individual sizes such as but not limited to 2 nm, 3 nm, 4 nm, and sub-ranges such as 10 nm to 50 nm, 20 nm to 100 nm, etc . . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. U.S. Provisional Application Ser. No. 61/121,902 filed Dec. 11, 2008 and fully incorporated herein for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A photovoltaic device with direct metal-to-glass bond moisture barrier.

2. A method comprising forming a solar module with direct metal-to-glass bond moisture barrier around an entire perimeter of the solar module.

3. A method comprising forming a solar module with direct metal-to-glass bond moisture barrier around at least 50% of the perimeter of the solar module.

4. The method according to claim 3 the area to be metal-to-glass bond moisture barrier bonded is pressed between an anvil with a roughed surface and an ultra sound barrier forming head that also has a roughened surface to form the barrier.

5. The method according to claim 3 wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide.
